(19) United States
(12) Patent Application Publication
(10) Pub. No.: US 2009/0053616 A1
(43) Pub. Date: Feb. 26, 2009

(54) HOLOGRAPHIC RECORDING MEDIUM

(75) Inventors: SATOSHI MIKOSHIBA, Yamato-shi (JP); Akiko Hirao, Kawasaki-shi (JP); Rumiko Hayase, Yokohama-shi (JP); Kazuki Matsumoto, Kawasaki-shi (JP); Norikatsu Sasao, Tokyo (JP); Takahiro Kamikawa, Kawasaki-shi (JP); Masahiro Kanamaru, Fuchu-shi (JP)

Correspondence Address: Charles N.J. Ruggiero, Esq.;Ohlandt, Greeley, Ruggiero & Perle, L.L.P., One Landmark Square, 10th Floor, Stamford, CT, 06901-2682, US

(73) Assignee: Kabushiki Kaisha Toshiba

(21) Appl. No.: 12/050,808

(22) Filed: Mar. 18, 2008

(30) Foreign Application Priority Data
Aug. 20, 2007 (JP) 2007-213880

(51) Int. Cl. G03F 7/00

(52) U.S. Cl. 430/2

(57) ABSTRACT

A holographic recording medium is provided, which includes a recording layer. The recording layer comprises a radical polymeric monomer having an aromatic ring-containing group and a polymeric group, a polymer matrix having the aromatic ring-containing group, and a photo-radical polymerization initiator.

### CROSS-REFERENCE TO RELATED APPLICATIONS

This application is based upon and claims the benefit of priority from prior Japanese Patent Application No. 2007-213880, filed Aug. 20, 2007, the entire contents of which are incorporated herein by reference.

### BACKGROUND OF THE INVENTION

1. Field of the Invention

This invention relates to a holographic recording medium and to an optical information recording/reconstructing apparatus.

2. Description of the Related Art

A holographic memory which records information as a hologram is now attracting many attentions as a recording medium of the next generation since it capable of performing a large capacity of recording. As the photosensitive composition for the holographic recording, there is known a composition comprising, for example, as main components, a radical polymeric monomer, a thermoplastic binder resin, a photo-radical polymerization initiator and a sensitizing dye. This photosensitive composition for the holographic recording is formed into a film, thereby obtaining a recording layer. Information is recorded in this recording layer through interference exposure.

When the recording layer has been subjected to the interference exposure, the regions thereof which are strongly irradiated with light are permitted to undergo the polymerization reaction of the radical polymeric monomer. The radical polymeric monomer diffuses from the regions where the intensity of exposure beam irradiated is weak to the regions where the intensity of exposure beam irradiated is strong, thereby generating the gradient of concentration in the recording layer. Namely, depending on the magnitude in intensity of the interference beam, differences in density of the radical polymeric monomer occur, thereby generating a difference in refractive index in the recording layer.

A recording medium comprising a three-dimensional cross-linking polymer matrix, and a radical polymeric monomer dispersed in the matrix has been recently proposed. In order to enhance the recording density, the radical polymeric monomer is required to be incorporated into the matrix at a high concentration. However, because of compatibility thereof with the matrix, it has been impossible to incorporate the radical polymeric monomer into the matrix at a high concentration. Furthermore, due to the polymerization of the radical polymeric monomer when optical recording, the recording layer sometimes shrinks locally. In that case, it may become impossible to accurately read out the information that has been recorded therein, thus raising problems.

### BRIEF SUMMARY OF THE INVENTION

A holographic recording medium according to one aspect of the present invention comprises a recording layer, the recording layer comprising a radical polymeric monomer having an aromatic ring-containing group and a polymeric group; a polymer matrix having the aromatic ring-containing group; and a photo-radical polymerization initiator.

An optical information recording/reconstructing apparatus according to another aspect of the present invention comprises: the aforementioned holographic recording medium; a recording portion for recording information in the medium; and a reconstructing portion for reconstructing the information recorded in the medium.

### BRIEF DESCRIPTION OF THE SEVERAL VIEWS OF THE DRAWING

FIG. 1 is a cross-sectional view schematically illustrating the transmission-type holographic recording medium according to one embodiment;

FIG. 2 is a diagram schematically illustrating the transmission-type holographic information recording/reconstructing apparatus;

FIG. 3 is a cross-sectional view schematically illustrating the reflection-type holographic recording medium according to another embodiment;

FIG. 4 is a diagram schematically illustrating the reflection-type holographic information recording/reconstructing apparatus;

FIG. 5 is a diagram schematically illustrating an optical information recording/reconstructing apparatus;

FIG. 6 is a diagram schematically illustrating an optical information recording/reconstructing apparatus;

FIG. 7 is a diagram showing a pattern of modulation in a reflection-type spatial beam modulator; and

FIG. 8 is a diagram showing a pattern of modulation in a reflection-type spatial beam modulator.

### DETAILED DESCRIPTION OF THE INVENTION

Next, the embodiments of the present invention will be explained.

The recording layer of the holographic recording medium according to one embodiment comprises a radical polymeric monomer having an aromatic ring-containing group and a polymeric group, a polymer matrix, and a photo-radical polymerization initiator.

In this recording layer, the radical polymeric monomer exists together with the photo-radical polymerization initiator in the polymer matrix. Therefore, it can be said that the polymer matrix is provided with portions which record information. When a light beam is irradiated onto a predetermined region of the recording layer, the radical polymeric monomer is caused to move from an unexposed region to the exposed region, thereby enabling the radical polymeric monomer existing in the exposed region to polymerize due to the effects of the photo-radical polymerization initiator. As a result, a difference in refractive index increases between the exposed region and the unexposed region. By this mechanism, the recording of information is performed. The recording density varies depending on the content of the radical polymeric monomer. Therefore, so long as the optical recording that has been created through the polymerization is not destroyed, the content of radical polymeric monomer in the recording layer should preferably be as large as possible.

The upper limit of the content of radical polymeric monomer in the recording layer is determined by the compatibility of radical polymeric monomer with the polymer matrix. The difference in refractive index Δn between the exposed region and the unexposed region should preferably be as large as possible. Although the refractive index may decrease corresponding to the exposure, it is generally employed a method whereby the refractive index increases corresponding to the exposure. In this case, the refractive index of the radical polymeric monomer to be employed is higher than the refractive index of the polymer matrix.

Generally speaking, the refractive index of aromatic group-containing group is relatively high and the refractive index of aliphatic hydrocarbon group is relatively low. Therefore, as long as the aromatic group-containing group is contained in the radical polymeric monomer, the refractive index of the radical polymeric monomer can be made higher than an average refractive index of the recording layer, and when the aliphatic hydrocarbon group moiety exists in a large amount in the polymer matrix, the refractive index of the polymer matrix can be made lower. However, a combination of this kind between the radical polymeric monomer and the polymer matrix leads, in many cases, to a great difference in polarity of molecule between these compounds, thus deteriorating the compatibility of radical polymeric monomer with the polymer matrix. As a result, it is no longer possible to incorporate a sufficient amount of the radical polymeric monomer into the polymer matrix, thus making it impossible to obtain a high recording density.

It has been succeeded by the present inventors to enhance the compatibility between the polymer matrix and the radical polymeric monomer by adopting a method wherein the aromatic ring-containing group included in the radical polymeric monomer is introduced into the polymer matrix. Due to the enhancement of compatibility as described above, it is now possible to increase the content of the radical polymeric monomer in the polymer matrix.

Further, the recording layer is required to be homogeneous as an optical material. If the polarity of the polymer matrix differs greatly from the polarity of the radical polymeric monomer, the radical polymeric monomer precipitates. Even if it is possible to suppress the precipitation, a region where the radical polymeric monomer is dense (the polymer matrix is sparse) as well as a region where the radical polymeric monomer is sparse (the polymer matrix is dense) exist in the recording layer. When the radical polymeric monomer exists in such a distribution as described above in the recording layer, the transmissivity and refractive index of recording layer fluctuate depending on the location within the same exposure region or within the same unexposure region, thus making it impossible to uniformly record information. Furthermore, since the reactivity of the radical polymeric monomer differs due to such a distribution of the radical polymeric monomer as described above, it may become difficult to perform the uniform recording of information. In this case, if the aromatic ring-containing group included in the radical polymeric monomer exist in the polymer matrix, it would be possible to enhance the uniformity in terms of molecules.

The content of the polymer matrix decreases correspondingly as the content of the radical polymeric monomer increases. When the polymer matrix is formed of an aliphatic polymer, the degree of freedom of molecular motion becomes higher so that it may become difficult to retain the recorded portion. When the aromatic ring-containing group included in the radical polymeric monomer exist in the polymer matrix, the portion where the aromatic ring-containing group exists is turned more rigid than the aliphatic polymer, so that the degree of freedom of molecular motion is restricted, thus suppressing the shrinkage of volume.

As described above, the aromatic ring-containing group that has been introduced into the polymer matrix is effective in creating a moving space of the radical polymeric monomer to be moved in the recording layer when recording. As a result, the moving velocity of the radical polymeric monomer is enhanced, resulting in the enhancement of the recording sensitivity.

The aromatic ring-containing group may be selected, for example, from phenyl group, phenylene group, naphthyl group, naphthylene group, carbazole group, etc. The benzene ring in these aromatic ring-containing groups may be partially substituted by halogen such as chlorine, bromine, iodine, etc.; a sulfuric compound such as thiol, methylthio group, ethylthio group, phenylthio group, etc.; alkyl group; and aromatic group; etc. On the other hand, the polymeric group may be selected from the group consisting, for example, of acrylic group, methacrylic group, vinyl group, epoxy group and oxetane group.

As examples of the radical polymeric monomer having these aromatic ring-containing groups and polymeric groups, they include, for example, vinylnaphthalene, vinylcarbazole, tribromophenyl acrylate, styrene, divinylphenylene, etc.

Vinylnaphthalene is provided with aromatic ring-containing group consisting of naphthalene group and with polymeric group consisting of vinyl group. Vinylcarbazole is provided with aromatic ring-containing group consisting of carbazole group and with polymeric group consisting of vinyl group. Tribromophenyl acrylate is provided with aromatic ring-containing group consisting of tribromophenyl group and with polymeric group consisting of acrylic group. Styrene is provided with aromatic ring-containing group consisting of phenyl group and with polymeric group consisting of vinyl group. Divinylphenylene is provided with aromatic ring-containing group consisting of phenylene group and with polymeric group consisting of vinyl group.

Further, the following compounds can be also employed as the radical polymeric monomer. Specifically, they include phenyl methacrylate, phenoxyethyl acrylate, chlorophenyl acrylate, vinyl pyridine, styrene, bromostyrene, chlorostyrene, tribromophenyl acrylate, trichlorophenyl acrylate, tribromophenyl methacrylate, trichlorophenyl methacrylate, vinyl benzoate, 3,5-dichlorovinyl benzoate, vinyl naphthalene, vinyl naphthoate, naphthyl methacrylate, naphthyl acrylate, N-phenyl methacryl amide, N-phenyl acryl amide, N-vinyl pyrrolidinone, N-vinyl carbazole, 1-vinyl imidazole, etc.

The content of the radical polymeric monomer in the recording layer should preferably be confined to the range of 1 to 40 parts by weight based on 100 parts by weight of the recording layer. If the content of the radical polymeric monomer is less than 1 part by weight, the recording density may be extremely deteriorated. Furthermore, due to an excessive content of the polymer matrix, the mobility of the radical polymeric monomer may be obstructed, resulting in the deterioration of recording sensitivity. On the other hand, if the content of the radical polymeric monomer exceeds 40 parts by weight, the optical recording that has been created may be easily deformed due to the relatively small content of the polymer matrix. In that case, it may become difficult to read out the information that has been recorded in the recording layer. More preferably, the content of the radical polymeric monomer should be confined to 5 to 15 parts by weight based on 100 parts by weight of the recording layer.

The same kind of aromatic ring-containing group as that contained in the radical polymeric monomer exist in the polymer matrix. Any desired aromatic ring-containing group can be introduced into the polymer matrix according to the following method for example. Namely, a desired polymer can be synthesized through the co-polymerization of epoxide monomer having an aromatic ring-containing group introduced therein. As the epoxide monomer, it is possible to employ, for example, epoxyethyl benzene, epoxyethyl naphthalene, epoxy carbazole, etc. These compounds may be partially substituted by halogen such as chlorine, bromine, iodine, etc.; a sulfuric compound such as thiol, methylthio group, ethylthio group, phenylthio group, etc.; alkyl group; and aromatic group; etc.

As examples of unsubstituted epoxyethyl benzene, they include, for example, 1-epoxyethyl benzene, 2-epoxyethyl benzene, etc. As examples of substituted epoxy ethylbenzene, they include, for example, epoxyethyl-bromobenzene, epoxyethyl-dibromobenzene, epoxyethyl-tribromodibromobenzene, epoxyethyl-chlorophenylbenzene, epoxyethyl-dichlorobenzene, epoxyethyl-trichlorobenzene, etc.

As examples of unsubstituted epoxyethyl naphthalene, they include, for example, 1-epoxyethyl naphthalene, 2-epoxyethyl naphthalene, etc. As examples of substituted naphthyl oxirane, they include, for example, epoxyethyl bromonaphthalene, epoxyethyl dibromonaphthalene, epoxyethyl tribromonaphthalene, epoxyethyl chloronaphthalene, epoxyethyl dichloronaphthalene, epoxyethyl trichloronaphthalene, epoxyethyl tetrachloronaphthalene, etc.

As examples of unsubstituted epoxycarbazole, they include, for example, N-epoxycarbazole, etc. As examples of substituted epoxycarbazole, they include, for example, bromoepoxycarbazole, dibromoepoxycarbazole, tribromoepoxycarbazole, chloroepoxycarbazole, dichloroepoxycarbazole, trichloroepoxycarbazole, etc.

In order to enable the effects of the aromatic ring-containing group to sufficiently exhibit, it is desirable that the aromatic ring-containing group exists in the polymer matrix at a content of at least about 0.01%. However, if the content of the aromatic ring-containing group is too high, the refractive index of the polymer matrix may increase. In order to prevent the increase of refractive index of the polymer matrix, the content of the aromatic ring-containing group in the polymer matrix should preferably be confined to the range of 0.01-0.5% or so.

The aromatic ring-containing group in the polymer matrix should preferably be bonded to the polymer matrix through chemical bonding. When the monomer to be employed as a raw material for the polymer matrix is constituted by vinylnaphthalene, naphthyl group or naphthylene group can be introduced into the polymer matrix. Although there is not any particular limitation with respect to the method of bonding the aromatic ring-containing group to the polymer matrix, when a linear polymer is to be synthesized using acrylic acid or methacrylic acid as a monomer, the aromatic ring-containing group can be introduced into the polymer matrix through the copolymerization thereof with naphthyl methacrylate or naphthyl acrylate.

When a three-dimensional cross-linking polymer matrix is to be created using epoxide monomer, the aromatic ring-containing group included in the radical polymeric monomer can be introduced into the polymer matrix through the synthesis of copolymer using a monomer having an epoxy functional group such as naphthyl oxirane. The ratio of the aromatic ring-containing group should preferably be confined, relative to the polymeric monomer to be utilized for the refractive index modulation, to such that the copolymerizable monomer thereof is limited to the range of 1 to 15 wt %, more preferably 1 to 7 wt %.

As the polymer matrix, it may be either a linear polymer or a three-dimensional cross-linking polymer. For the purpose of suppressing the shrinkage of film, it is more preferable to employ three-dimensional cross-linking polymer. The three-dimensional cross-linking polymer can be obtained through various polymerization methods such as epoxy-amine polymerization, epoxy-acid anhydride polymerization, and epoxy homopolymerization.

As the amine to be employed in the epoxy-amine polymerization, it is possible to employ any kind of amine compound which is capable of obtaining a cured substance through the reaction thereof with diglycidyl ether selected from the group consisting of 1,6-hexanediol diglycidyl ether, and diethylene glycol diglycidyl ether.

More specifically, examples of the amine include ethylene diamine, diethylene triamine, triethylene tetramine, tetraethylene pentamine, pentaethylene hexamine, hexamethylene diamine, menthene diamine, isophorone diamine, bis(4-amino-3-methyldicyclohexyl)methane, bis(aminomethyl)cyclohexane, N-aminoethyl piperazine, m-xylylene diamine, 1,3-diaminopropane, 1,4-diaminobutane, trimethylhexamethylene diamine, iminobispropyl amine, bis(hexamethylene)triamine, 1,3,6-trisaminomethylhexane, dimethylaminopropyl amine, aminoethyl ethanol amine, tri(methylamino) hexane, m-phenylene diamine, p-phenylene diamine, diaminodiphenyl methane, diaminodiphenyl sulfone, 3,3′-dietheyl-4,4′-diaminodiphenyl methane, etc.

Since aliphatic primary amine can be cured quickly and at room temperature, it can be preferably employed. Among them, diethylene triamine, triethylene tetramine, tetraethylene pentamine, pentaethylene hexamine and iminobispropyl amine are especially preferable. The mixing ratio of these amines relative to the oxirane of 1,6-hexanediol diglycidyl ether or diethylene glycol diglycidyl ether should preferably be confined to such that the NH— of amine is 0.6-2 times as high as the equivalent weight. When this mixing ratio of these amines is less than 0.6 time or more than twice the equivalent weight, the resolution may be deteriorated.

As the epoxide monomer, it is possible to employ, for example, glycidyl ether. More specifically, More specifically, examples of the epoxide monomer include ethylene glycol diglycidyl ether, 1,4-butanediol diglycidyl ether, 1,5-pentanediol diglycidyl ether, 1,6-hexanediol diglycidyl ether, 1,8-octanediol diglycidyl ether, 1,10-decanediol diglycidyl ether, 1,12-dodecanediol diglycidyl ether, etc.

The epoxy homopolymer can be synthesized through the cationic polymerization of epoxide monomer. As examples of the epoxide monomer useful in this case, they include ethylene glycol diglycidyl ether, 1,4-butanediol diglycidyl ether, 1,5-pentanediol diglycidyl ether, 1,6-hexanediol diglycidyl ether, 1,8-octanediol diglycidyl ether, 1,10-decanediol diglycidyl ether, 1,12-dodecanediol diglycidyl ether, etc.

When the easiness of moving of the radical polymeric monomer in the polymer matrix is taken into consideration, the epoxide monomer should preferably be selected from the compounds represented by the following general formula (1).

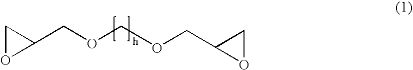

(In the general formula (1), h is an integer ranging from 8 to 12)

Specific examples of the compounds represented by the general formula (1) include 1,4-butanediol diglycidyl ether, 1,5-pentanediol diglycidyl ether, 1,6-hexanediol diglycidyl ether, 1,8-octanediol diglycidyl ether, 1,10-decanediol diglycidyl ether, and 1,12-dodecanediol diglycidyl ether.

The cationic polymerization of the epoxide monomer can be carried out using a metal complex and alkyl silanol both acting as a catalyst.

As the metal complex, it is possible to employ the compounds represented by the following general formulas (2), (3) and (4):

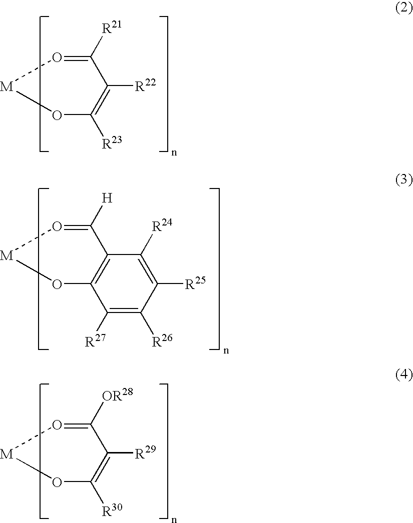

(In the general formulas (2), (3) and (4), M is selected from the group consisting of Al, Ti, Cr, Mn, Fe, Co, Ni, Cu, Zr, Zn, Ba, Ca, Ce, Pb, Mg, Sn and V; R²¹, R²² and R²³ may be the same or different and are individually hydrogen atom, substituted or unsubstituted alkyl group having 1 to 10 carbon atoms; R²⁴, R²⁵, R²⁶ and R²⁷ may be the same or different and are individually hydrogen atom, substituted or unsubstituted alkyl group having 1 to 10 carbon atoms; R²⁸, R²⁹ and R³⁰ may be the same or different and are individually hydrogen atom, substituted or unsubstituted alkyl group having 1 to 10 carbon atoms; and n is an integer of 2 to 4)

When the compatibility of the metal complex with the three-dimensional cross-linking polymer matrix and the catalytic capacity thereof are taken into consideration, the M in these general formulas (2), (3) and (4) should preferably be selected from aluminum (Al) and zirconium (Zr), and R²¹—R³⁰ should preferably be selected from alkyl acetyl acetate such as acetyl acetone, methylacetyl acetate, ethylacetyl acetate, propylacetyl acetate, etc. Among them, the most preferable metal complex is aluminum tris(ethylacetyl acetate).

As the alkyl silanol, it is possible to employ compounds represented by the following general formula (5).

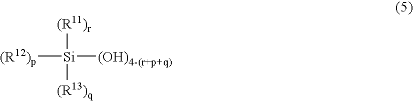

(In the general formula (5), R¹¹, R¹² and R¹³ may be the same or different and are individually substituted or unsubstituted alkyl group having 1 to 30 carbon atoms, substituted or unsubstituted aromatic group having 6 to 30 carbon atoms, or substituted or unsubstituted aromatic heterocyclic group having 3 to 30 carbon atoms; and p, q and r are individually an integer of 0 to 3 with a proviso that p+q+r is 3 or less)

As examples of the alkyl group to be introduced as R¹¹, R¹² and R¹³ into the general formula (5), they include, for example, methyl, ethyl, propyl, butyl, pentyl, hexyl, etc. As examples of the aromatic group to be introduced as R¹¹, R¹² and R¹³ into the general formula (2), they include, for example, phenyl, naphthyl, tolyl, xylyl, cumenyl, mesityl, etc. As examples of the aromatic heterocyclic group to be introduced as R¹¹, R¹² and R¹³ into the general formula (2), they include, for example, pyridyl, quinolyl, etc. At least one of hydrogen atoms in these alkyl group, aromatic group and aromatic heterocyclic group may be substituted by a substituent group such as halogen atom, etc.

Specific examples of alkyl silanol include diphenyl disilanol, triphenyl silanol, trimethyl silanol, triethyl silanol, diphenyl silanediol, dimethyl silanediol, diethyl silanediol, phenyl silanediol, methyl silanetriol, ethyl silanetriol, etc. When the compatibility of alkyl silanol with the three-dimensional cross-linking polymer matrix and the catalytic capacity thereof are taken into consideration, the employment of diphenyl disilanol or triphenyl silanol is preferable as the alkyl silanol.

The phenolic compound represented by the following general formula (6) can be employed as a compound having almost the same effects as the alkyl silanol represented by the aforementioned general formula (5).

R¹⁴—Ar—OH (6)

(In the general formula (6), R¹⁴ is substituted or unsubstituted alkyl group having 1 to 30 carbon atoms, or substituted aromatic group having 6 to 30 carbon atoms; and Ar is substituted or unsubstituted aromatic group having 3 to 30 carbon atoms)

As examples of the alkyl group to be introduced as R¹⁴ into the general formula (6), they include, for example, methyl, ethyl, propyl, butyl, pentyl, hexyl, trifluoromethyl, pentafluoroethyl, etc. At least one of hydrogen atoms in the alkyl group may be substituted by a substituent group such as halogen atom, etc.

As examples of the substituted aromatic group that can be introduced as R¹⁴ into the general formula (6), they include, for example, HO(C₆H₆)SO₂—, HO(C₆H₆)C(CH₃)₂—, HO(C₆H₆)CH₂—, etc.

As examples of the aromatic group that can be introduced as Ar into the general formula (6), they include, for example, phenyl, naphthyl, tolyl, xylyl, cumenyl, mesityl, etc. At least one of hydrogen atoms in the aromatic group may be substituted by the aforementioned substituent group.

Since the phenolic compound represented by the aforementioned general formula (6) is capable of executing substitution reaction with the ligand of the metal complex, the phenolic compound is enabled to exhibit almost the same effects as the alkyl silanol represented by the aforementioned general formula (5).

As examples of the phenolic compound represented by the aforementioned general formula (6), they include HO(C₆H₆)SO₂(C₆H₆)OH, HO(C₆H₆)CH₂(C₆H₆)OH, HO(C₆H₆)C(CH₃)₂(C₆H₆)OH, CF₃(C₆H₆)OH, CF₃CF₂(C₆H₆)OH, etc. When the compatibility of phenolic compound with the three-dimensional cross-linking polymer matrix and the catalytic capacity thereof are taken into consideration, the employment of CF₃(C₆H₆)OH or HO(C₆H₆)SO₂(C₆H₆)OH is preferable as the phenolic compound.

A cationic polymerization catalyst which is composed of a combination of the alkyl silanol represented by the aforementioned general formula (5) with the metal complex represented by any one of the aforementioned general formulas (2), (3) and (4) is capable of proceeding the polymerization reaction of the radical polymeric monomer at room temperature (around 25° C.). Therefore, it is possible to form the three-dimensional cross-linking polymer matrix without necessitating the application of heat history to the radical polymeric monomer and to the photo-radical polymerization initiator.

Even when the alkyl silanol is replaced by the phenolic compound represented by the aforementioned general formula (6), almost the same effects as described above can be obtained.

Moreover, the catalytic components such as the alkyl silanol represented by the aforementioned general formula (5), the phenolic compound represented by the aforementioned general formula (6) and the metal complex represented by any one of the aforementioned general formulas (2), (3) and (4) are enabled to exist in the three-dimensional cross-linking polymer matrix without reacting with this polymer matrix that has been obtained through the polymerization. Further, the generation of ionic impurities can be prevented.

When light or beam is irradiated onto a predetermined region of the recording layer comprising the three-dimensional cross-linking polymer matrix, the radical polymeric monomer and the photo-radical polymerization initiator to perform the exposure of the recording layer, the radical polymeric monomer is caused to move to the exposed region. The space created by this movement of the radical polymeric monomer is then occupied by the catalytic components existing in the polymer matrix. As a result, the change in refractive index becomes more prominent.

Even if a reaction between the catalytic components happens to generate, there would be raised no problem. Since it is possible to prevent violent reaction and hence to retard the reaction rate, resulting in easiness to control the shrinkage and strain of the recording medium, it is more preferable to employ the phenolic compound represented by the general formula (6) rather than the alkyl silanol represented by the general formula (5).

Further, these catalytic components would not generate decomposition products such as alcohol or impurities. Water is not required to be existed in the recording medium when effecting the catalytic action and therefore it is possible to employ a recording medium in a stable dried state.

The catalytic components such as the metal complex and alkyl silanol described above act to strengthen the adhesion between the substrate sustaining the recording medium and the recording layer. When a molecule which is highly polarized therein such as the metal complex co-exists with the hydroxyl group of silanol in the recording layer, the adhesion of the recording layer to various kinds of substrates such as those made of glass, polycarbonate, acrylic resin, polyethylene terephthalate (PET), etc., can be enhanced.

When the adhesion of the recording layer to the substrate is enhanced, it is possible to prevent the peel-off of the recording layer even if the shrinkage or expansion of volume generate at a minute exposed region or unexposed region when writing information by interference light wave. Since the information thus recorded can be retained without generating any distortion, it is possible to further enhance the recording performance. Further, the metal complex and alkyl silanol exist in the polymer matrix without being deactivated.

For this reason, the information thus written can be fixed through the post-baking of the recording medium, thus making it possible to prevent the changes with time of the information. When the recording medium is subjected to exposure by interference light wave, the radical polymeric monomer polymerizes to increase the density of the exposed region, thus increasing the refractive index. On the other hand, at the unexposed region, the density thereof is reduced due to the movement of the radical polymeric monomer therefrom, thus decreasing the refractive index. The movement of the radical polymeric monomer in this case can be increasingly facilitated as the polymer matrix of the recording medium is lower in density. Namely, as the density of cross-linking of the three-dimensional cross-linking polymer matrix becomes lower, the movement of the radical polymeric monomer can be increasingly facilitated, thus giving a recording medium which is higher in sensitivity.

However, in the case of the three-dimensional cross-linking polymer matrix which is low in the density of cross-linking, the radical polymeric monomer or the polymer thereof is liable to move into an unexposed region which is spatially low in density. Therefore, the density of cross-linking of the polymer matrix should preferably be decreased so as to enable the radical polymeric monomer to more easily move when recording information through the exposure of recording layer to an interference light wave. After the information has been written in the recording layer however, when the information is desired to be fixed, it will be effective to enhance the density of cross-linking of the polymer matrix by post-baking. Since the recording medium according to one embodiment is enabled to increase the density of cross-linking of the polymer matrix by post-baking, the recording performance of the recording medium can be improved.

The post-baking should preferably be performed at a temperature ranging from 40° C. to 100° C. If the temperature of post-baking is lower than 40° C., it may become difficult to enhance the density of cross-linking of the polymer matrix. On the other hand, if the temperature of post-baking exceeds 100° C., the molecular motion of the polymer matrix would be activated, thereby possibly making it impossible to read out the recorded information as the information recorded therein changes.

As described above, when recording the information by interference light wave, the density of the recording layer increases at the exposed region, while the density of unexposed region is reduced. Due to a difference in density of the recording layer, the catalytic components such as the metal complex and alkyl silanol move from the exposed region to the unexposed region. This movement of these catalytic components promotes the moving of the radical polymeric monomer to the exposed region. Further, the catalytic components that have been moved to the unexposed region of the recording layer act to lower the refractive index of the unexposed region thereof.

The three-dimensional cross-linking polymer matrix (the cured product of epoxy resin) that has been polymerized using the metal complex and alkyl silanol as catalysts is transparent to the light ranging from visible light to ultraviolet ray and has an optimal hardness. Namely, since the polymer matrix is transparent to the exposure wavelength, the absorption of light by the photo-radical polymerization initiator cannot be obstructed, thereby making it possible to obtain a three-dimensional cross-linking polymer matrix having a suitable degree of hardness for enabling the radical polymeric monomer to appropriately diffuse therein. As a result, it is now possible to manufacture a holographic recording medium which is excellent in sensitivity and diffraction efficiency. Furthermore, since the three-dimensional cross-linking polymer matrix has a suitable degree of hardness, it is possible to inhibit the recording layer from being shrunk at the region where the polymerization of the radical polymeric monomer has taken place.

The employment of the aforementioned epoxide monomer in the formation of the three-dimensional cross-linking polymer matrix is advantageous in the following respects. Namely, when the aforementioned epoxide monomer is employed, it is possible to obviate any possibility of obstructing the moving of the radical polymeric monomer to be generated on the occasion of exposure. The reasons for this can be explained as follows. First of all, it is possible to secure a sufficient space for enabling the radical polymeric monomer to move in the three-dimensional cross-linking polymer matrix. Further, there is little possibility of locally enhancing the density of cross-linking. Furthermore, since the polarity of the polymer matrix is low, the movement of the radical polymeric monomer cannot be obstructed. Therefore, it is now possible to excellently perform the writing of hologram.

In addition to the aforementioned radical polymeric monomer and polymer matrix, a photo-radical polymerization initiator is included in the recording layer of the holographic recording medium according to one embodiment.

As the photo-radical polymerization initiator, it is possible to employ, for example, imidazole derivatives, organic azide compounds, titanocene, organic peroxides, and thioxanthone derivatives. Specific examples of the photo-radical polymerization initiator include benzyl, benzoin, benzoin ethyl ether, benzoin isopropyl ether, benzoin butyl ether, benzoin isobutyl ether, 1-hydroxycyclohexyl phenyl ketone, benzyl methyl ketal, benzyl ethyl ketal, benzyl methoxyethyl ether, 2,2′-diethylacetophenone, 2,2′-dipropylacetophenone, 2-hydroxy-2-methylpropiophenone, p-tert-butyltrichloroacetophenone, thioxanthone, 2-chlorothioxanthone, 3,3′,4,4′-tetra(t-butyl peroxycarbonyl)benzophenone, 2,4,6-tris(trichloromethyl)1,3,5-triazine, 2-(p-methoxyphenyl)-4,6-bis(trichloromethyl)1,3,5-triazine, 2-[(p-methoxyphenyl)ethylene]-4,6-bis(trichloromethyl)1,3,5-triazine, Irgacure 149, 184, 369, 651, 784, 819, 907, 1700, 1800, 1850 (Chiba Speciality Chemicals Co., Ltd.), di-t-butyl peroxide, dicumyl peroxide, t-butylcumyl peroxide, t-butyl peroxyacetate, t-butyl peroxyphthalate, t-butyl peroxybenzoate, acetyl peroxide, isobutyryl peroxide, decanoyl peroxide, lauroyl peroxide, benzoyl peroxide, t-butyl hydroperoxide, cumene hydroperoxide, methylethyl ketone peroxide, cyclohexanone peroxide, etc.

These photo-radical polymerization initiators should preferably be incorporated in the raw material solution at a content ranging from 0.1 to 10% by weight based on the radical polymeric monomer. If the content of these photo-radical polymerization initiators is less than 0.1% by weight, it may become impossible to obtain a sufficient change in refractive index. On the other hand, if the content of these photo-radical polymerization initiators exceeds 10% by weight, the light absorption by the recording layer would become too large, thus possibly deteriorating the resolution. More preferably, the content of the photo-radical polymerization initiator should be confined to 0.5 to 6% by weight based on the radical polymeric monomer.

If necessary, a sensitizing dye such as cyanine, merocyanine, xanthene, coumalin, eosin, etc.; a silane coupling agent and a plasticizer may be incorporated in the raw material solution for the recording layer.

Predetermined components described above are mixed together to prepare the raw material solution for the recording layer. Using the raw material solution for the recording layer thus prepared, a resin layer is deposited on the predetermined substrate and then the polymer matrix is created, thus forming the recording layer.

For example, the raw material solution for the recording layer is coated on the light-transmitting substrate to form a resin layer. As the light-transmitting substrate, it is possible, for example, a glass substrate or a plastic substrate. The coating of the raw material solution can be performed by casting or spin-coating method. Alternatively, the raw material solution for the recording layer may be poured into a space formed between a pair of superimposed glass substrates with a resin spacer being interposed therebetween, thus forming a resin layer.

The resin layer thus formed is then heated by an oven, a hot plate, etc., to allow the radical polymerization of epoxide monomer to proceed, thus forming the three-dimensional cross-linking polymer matrix. The temperature in this heating step should be confined within the range of 10° C. to less than 80° C., more preferably 10° C. to less than 60° C. If this heating temperature is lower than 10° C., it may become difficult to create the three-dimensional cross-linking. On the other hand, if this heating temperature is 80° C. or more, the polymerization reaction may become vigorous, thereby narrowing the voids of the three-dimensional cross-linking polymer matrix, so that the moving velocity of the radical polymeric monomer in the polymer matrix may be reduced. Further, if this heating temperature is 80° C. or more, the reaction of radical polymeric monomer may take place. Since this reaction can take place sufficiently even at room temperature, it is preferable to employ a method to cure the resin layer at room temperature.

In the case of the method where the three-dimensional cross-linking polymer matrix is to be formed in a precursor of the recording layer as described above, the solubility of the radical polymeric monomer to the precursor of three-dimensional cross-linking polymer matrix constituting a major component becomes a key. Even when the radical polymeric monomer is enabled to sufficiently dissolve in the precursor of three-dimensional cross-linking polymer matrix, there is a possibility that the solubility of the radical polymeric monomer changes due to the reaction of the precursor of three-dimensional cross-linking polymer matrix, resulting in the separating of radical polymeric monomer. This may be ascribed to the phenomenon that, due to the reaction of the three-dimensional cross-linking polymer matrix, changes in polarity and free volume of the three-dimensional cross-linking polymer matrix as well as the phase change thereof from liquid phase to solid phase take place, thereby changing the solubility and/or the compatibility of the radical polymeric monomer. In order to inhibit such a separating of radical polymeric monomer, it is required that the polymer matrix contains the same aromatic ring-containing group that is contained in the radical polymeric monomer.

As the film thickness of the recording layer, it should preferably be confined within the range of 0.1 to 5 mm. If the film thickness of the recording layer is less than 0.1 mm, the angular resolution may deteriorate, thereby making it difficult to perform multiple recording. On the other hand, if the film thickness of the recording layer exceeds 5 mm, the transmissivity of the recording layer may be reduced, thus deteriorating the performance of the recording layer. More preferably, the film thickness of the recording layer should be confined within the range of 0.2 to 2 mm.

When performing the recording in the holographic recording medium according to one embodiment, information beam as well as reference beam is irradiated into the recording medium. By enabling these two beams to interfere in the interior of the recording layer, the recording or the reconstruction of the hologram is performed. As the type of hologram (holography) to be recorded, it may be either a transmission-type hologram (transmission-type holography) or a reflection-type hologram (reflection-type holography). As the method of generating the interference between the information beam and the reference beam, it may be a two-beam interference method or a coaxial interference method.

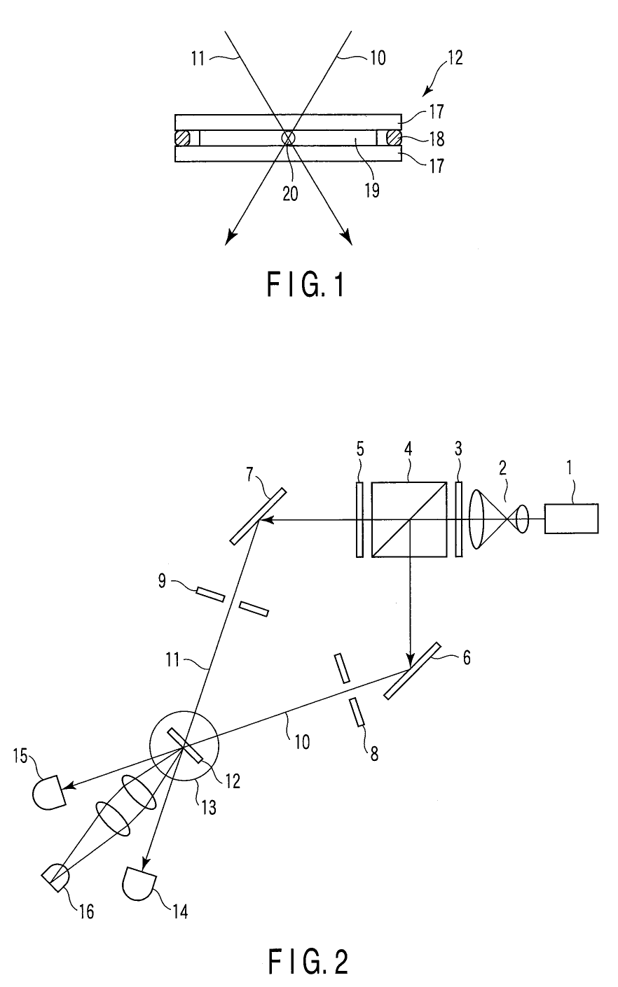

FIG. 1 shows a diagram schematically illustrating the holographic recording medium to be employed in the two-beam interference holography and also illustrating the information beam and the reference beam to be irradiated in the vicinity of the holographic recording medium. As shown in FIG. 1, the holographic recording medium 12 is provided with a pair of transparent substrates 17, between which a spacer 18 and a recording layer 19 are sandwiched. The transparent substrates 17 are respectively made of glass or plastics such as polycarbonate. The recording layer 19 comprises a specific kind of three-dimensional cross-linking polymer matrix as described above, a radical polymeric monomer, and a photo-radical polymerization initiator.

As an information beam 10 and a reference beam 11 are irradiated onto the holographic recording medium 12, these beams are intersected in the recording layer 19. As a result, an interference generates between these beams, thereby creating a transmission-type hologram in the modulated region 20.

FIG. 2 is a diagram schematically illustrating one example of the holographic information recording/reconstructing apparatus. The holographic information recording/reconstructing apparatus shown in FIG. 2 is a holographic photo-information recording/reconstructing apparatus where a transmission-type two-beam interference method is utilized.

The beam irradiated from a light source device 1 is introduced, via a beam expander 2 and an optical element 3 for optical rotation, into a polarized beam splitter 4. As the light source device 1, it is possible to employ a light source which is capable of irradiating any kind of light which can be interfered in the recording layer 19 of the holographic recording medium 12. However, in view of coherence, it is preferable to employ a linearly polarized laser. As the laser, it is possible to employ a semiconductor laser, an He—Ne laser, an argon laser and a YAG laser.

The beam expander 2 acts to expand the diameter of beam irradiated from the light source device 1 to such an extent that the expanded beam is suited for the hologram recording. The optical element 3 for optical rotation acts to bring about the optical rotation of the beam that has been expanded by the beam expander 2, thereby generating a beam comprising an S-polarized beam component and a P-polarized beam component. As the optical element 3 for optical rotation, it is possible to employ, for example, a half- or quarter-wavelength plate.

Among these beams that have passed through the optical element 3, the S-polarized beam component is reflected by the polarized beam splitter 4 to create an information beam 10, and the P-polarized beam component passes through the polarized beam splitter 4 to create a reference beam 11. It should be noted that in order to make the strength of information beam 10 identical with that of the reference beam 11 at the position of the recording layer 19 of the holographic recording medium 12, the direction of optical rotation of beam entering into the polarized beam splitter 4 is adjusted by the optical element 3.

The information beam 10 that has been reflected by the polarized beam splitter 4 is again reflected by a mirror 6 and then permitted to pass through an electromagnetic shutter 8 and to irradiate the recording layer 19 of the holographic recording medium 12 which is sustained on a rotary stage 13.

On the other hand, the reference beam 11 that has passed through the polarized beam splitter 4 is caused to rotate by 90° in the direction of polarization at an optical element 5 for optical rotation, thereby creating an S-polarized beam. This S-polarized beam is then reflected by a mirror 7 and permitted to pass through an electromagnetic shutter 9. Thereafter, the S-polarized beam is irradiated so as to intersect with the information beam 10 at a location inside the recording layer 19 of the holographic recording medium 12 which is sustained on a rotary stage 13, thereby creating a transmission-type hologram formed as a refractive index-modulating region 20.

When reconstructing the information thus recorded, the electromagnetic shutter 8 is closed to shut off the information beam 10, while enabling only the reference beam 11 to irradiate the transmission-type hologram (the refractive index-modulating region 20) which has been created in the recording layer 19 of the holographic recording medium 12. Part of the reference beam 11 is diffracted by the transmission-type hologram as it passes through the holographic recording medium 12. The resultant diffracted beam is then detected by a beam detector 15. A reference numeral 14 denotes a beam detector for monitoring the beam passing through the recording medium.

After the holographic recording, in order to stabilize the hologram that has been recorded through the polymerization of unreacted radical polymeric monomer, an ultraviolet source device 16 and an ultraviolet ray irradiating optical system may be installed as shown in FIG. 2. As this ultraviolet source device 16, it is possible to employ any kind of light source which is capable of irradiating the light that is effective in polymerizing the unreacted radical polymeric monomer. Because of excellence in ultraviolet ray-emitting efficiency, it is preferable to employ, for example, a xenon lamp, a mercury lamp, a high-pressure mercury lamp, a mercury xenon lamp, a gallium nitride-based emission diode, a gallium nitride-based semiconductor laser, an excimer laser, a tertiary harmonics (355 nm) of Nd:YAG laser, and a quaternary harmonics (266 nm) of Nd:YAG laser.

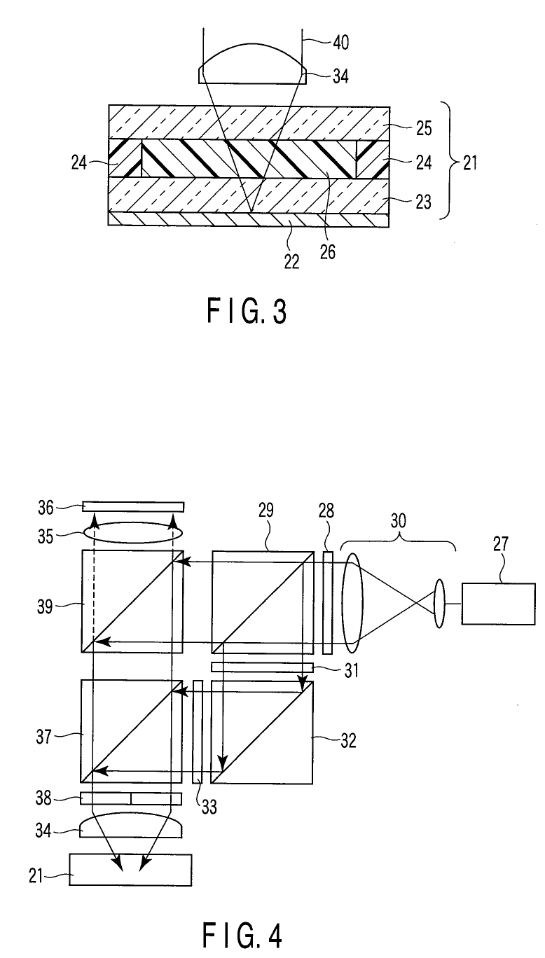

The recording medium according to one embodiment can be employed also as a reflection-type hologram recording medium. In this case, the recording of information can be performed as shown in FIG. 3 for example. FIG. 3 is a cross-sectional view schematically illustrating the reflection-type holographic recording medium as well as the information beam and the reference beam to be irradiated in the vicinity of the holographic recording medium. As shown in FIG. 3, the holographic recording medium 21 is constituted by a pair of transparent substrates 23 and 25 each made of glass or plastics such as polycarbonate, by a spacer 24 and a recording layer 26 which are sandwiched between these transparent substrates 23 and 25, and by a reflection layer 22 sustaining the substrate 23. The recording layer 26 comprises a specific kind of three-dimensional cross-linking polymer matrix described above, a radical polymeric monomer, and a photo-radical polymerization initiator.

As in the case of the transmission-type hologram, even in the case of this reflection-type hologram recording medium 21, an information beam and a reference beam 40 are irradiated into the holographic recording medium 21 so as to be intersected in the recording layer 26, thereby generating an interference between these beams and creating a reflection-type hologram in the modulated region (not shown).

Next, the method of recording information to the reflection-type holographic recording medium 21 will be explained with reference to FIG. 4.

As in the case of the transmission-type holographic recording/reconstructing apparatus, the light source device 27 of the holographic recording/reconstructing apparatus shown in FIG. 4 should preferably be one using a laser which emits a linearly polarized coherent beam. As examples of such a laser, it is possible to employ a semiconductor laser, an He—Ne laser, an argon laser and a YAG laser.

The beam emitted from the light source device 27 is expanded in beam diameter by the beam expander 30 and then transmitted as a parallel beam to the optical element 28 for optical rotation.

The optical element 28 for optical rotation is constructed such that it is enabled to emit, through the rotation of the plane of polarization of the previous beam of light, a beam comprising a polarized beam component where the plane of polarization is parallel with the plane of drawing (hereinafter referred to as a P-polarized beam component) and a polarized beam component where the plane of polarization is perpendicular to the plane of drawing (hereinafter referred to as a S-polarized beam component). Alternatively, it is possible to enable the optical element 28 to emit, by making the previous beam of light into a circularly polarized light or an elliptically polarized light, a beam comprising a polarized beam component where the plane of polarization is parallel with the plane of drawing and a polarized beam component where the plane of polarization is perpendicular to the plane of drawing. As the optical element 28 for optical rotation, it is possible to employ, for example, a half- or quarter-wavelength plate.

Among these beams that have been emitted from the optical element 28, the S-polarized beam component is reflected by the polarized beam splitter 29 and hence transmitted to a transmission-type spatial beam modulator 31. Meanwhile, the P-polarized beam component passes through the polarized beam splitter 29. This P-polarized beam component is utilized as a reference beam.

The transmission-type spatial beam modulator 31 is provided with a large number of pixels which are arrayed matrix-like as in the case of a transmission-type liquid crystal display device for example, so that the beam emitted from this spatial beam modulator 31 can be switched from the P-polarized beam component to the S-polarized beam component and vice versa for each pixel. In this manner, the transmission-type spatial beam modulator 31 is designed to emit the information beam provided with a two-dimensional distribution regarding the plane of polarization in conformity with the information to be recorded.

The information beam emitted from this spatial beam modulator 31 is then permitted to enter into another polarized beam splitter 32. This polarized beam splitter 32 acts to reflect only the S-polarized beam component out of the previous information beam while permitting the P-polarized beam component to pass therethrough.

The S-polarized beam component that has been reflected by the polarized beam splitter 32 is permitted to pass, as an information beam provided with a two-dimensional intensity distribution, through the electromagnetic shutter 33 and to enter into another polarized beam splitter 37. This information beam is then reflected by the polarized beam splitter 37 and permitted to enter into a halving optical element 38 for optical rotation.

This halving optical element 38 for optical rotation is constructed such that it is partitioned into a right side portion and a left side portion, which differ in optical properties from each other. Specifically, among the information beams, for example, the beam component entering into the right side portion of this halving optical element 38 is permitted to emit therefrom after the plane of polarization thereof has been rotated by an angle of +45° while the beam component entering into the left side portion of this halving optical element 38 is permitted to emit therefrom after the plane of polarization thereof has been rotated by an angle of −45°. The beam component to be derived from the S-polarized beam component whose polarization plane has been rotated by an angle of +45° (or the beam component to be derived from the P-polarized beam component whose polarization plane has been rotated by an angle of −45°) will be hereinafter referred to as an A-polarized beam component, the beam component to be derived from the S-polarized beam component whose polarization plane has been rotated by an angle of −45° (or the beam component to be derived from the P-polarized beam component whose polarization plane has been rotated by an angle of +45°) will be hereinafter referred to as a B-polarized beam component. It should be noted that each of the right and left portions of the halving optical element 38 may be constructed by a half-wavelength plate.

The A-polarized beam component and the B-polarized beam component that have been emitted from the halving optical element 38 are converged on the reflection layer 22 of holographic recording medium 21 by an objective lens 34. The holographic recording medium 21 is arranged such that the transparent substrate 25 faces the objective lens 34.

On the other hand, part of the P-polarized beam component (reference beam) that has passed through the polarized beam splitter 29 is reflected by the beam splitter 39 and then permitted to pass through the polarized beam splitter 37. This reference beam that has passed through the polarized beam splitter 37 is then transmitted into the halving optical element 38. The beam component entering into the right side portion of this halving optical element 38 is permitted to emit therefrom as a B-polarized beam component after the plane of polarization thereof has been rotated by an angle of +45° while the beam component entering into the left side portion of this halving optical element 38 is permitted to emit therefrom as an A-polarized beam component after the plane of polarization thereof has been rotated by an angle of −45°. Subsequently, these A-polarized beam component and B-polarized beam component are converged on the reflection layer 22 of holographic recording medium 21 by an objective lens 34.

As described above, the information beam constituted by the A-polarized beam component and the reference beam constituted by the B-polarized beam component are emitted from the right side portion of the halving optical element 38. On the other hand, the information beam constituted by the B-polarized beam component and the reference beam constituted by the A-polarized beam component are emitted from the left side portion of the halving optical element 38. Furthermore, these information beam and reference beam are converged on the reflection layer 22 of holographic recording medium 21.

Because of this, the interference between the information beam and the reference beam takes place only between the information beam formed of the direct beam that has been directly transmitted into the recording layer 26 through the transparent substrate 25 and the reference beam formed of the reflection beam that has been reflected by the reflection layer 22, and between the reference beam formed of a direct beam and the information beam formed of a reflection beam. Furthermore, not only the interference between the information beam formed from a direct beam and the information beam formed from a reflection beam, but also the interference between the reference beam formed from a direct beam and the reference beam formed from a reflection beam can be prevented from generating. Therefore, according to the recording/reconstructing apparatus shown in FIG. 4, it is possible to generate a distribution of optical properties in the recording layer 26 in conformity with the information beam.

In the case of the reflection-type holographic recording/reconstructing apparatus shown in FIG. 4, it is possible to install the ultraviolet source device and the ultraviolet irradiating optical system as already explained above in order to enhance the stability of the recorded hologram.

The information recorded according to the aforementioned method can be read out as explained below. Namely, the electromagnetic shutter 33 is closed to enable only the reference beam to emit, thus irradiating the recording layer 26 having information recorded therein in advance. As a result, only the reference beam formed of the P-polarized beam component reaches the halving optical element 38.

Due to the effects of the halving optical element 38, this reference beam is processed such that the beam component entering into the right side portion of this halving optical element 38 is emitted therefrom as a B-polarized beam component after the plane of polarization thereof has been rotated by an angle of +45° while the beam component entering into the left side portion of this halving optical element 38 is emitted therefrom as an A-polarized beam component after the plane of polarization thereof has been rotated by an angle of −45°. Subsequently, these A-polarized beam component and B-polarized beam component are converged on the reflection layer 22 of holographic recording medium 21 by the objective lens 34.

In the recording layer 26 of the holographic recording medium 21, there is formed, according to the aforementioned method, a distribution of optical properties created in conformity with the information to be recorded. Accordingly, part of these A-polarized beam component and B-polarized beam component that have been emitted to the holographic recording medium 21 is diffracted by the distribution of optical properties created in the recording layer 26 and is then emitted as a reconstructing beam from the holographic recording medium 21.

In the reconstructing beam emitted from the holographic recording medium 21, the information beam is reproduced therein, so that the reconstructing beam is formed into a parallel beam by the objective lens 34 and then permitted to reach the halving optical element 38. The B-polarized beam component transmitted into the right side portion of the halving optical element 38 is emitted therefrom as the P-polarized beam component. Further, the A-polarized beam component transmitted into the left side portion of the halving optical element 38 is emitted therefrom also as the P-polarized beam component. In this manner, it is possible to obtain a reconstructing beam as the P-polarized beam component.

Thereafter, the reconstructed beam passes through the polarized beam splitter 37. Part of the reconstructing beam that has passed through the polarized beam splitter 37 is then permitted to pass through the beam splitter 39 and transmitted through an image-forming lens 35 to the two-dimensional beam detector 36, thereby reproducing an image of the transmission-type spatial beam modulator 31 on the two-dimensional beam detector 36. In this manner, it is possible to read out the information recorded in the holographic recording medium 21.

On the other hand, the rests of the A-polarized beam component and of the B-polarized beam component that have transmitted through the halving optical element 38 into the holographic recording medium 21 are reflected by the reflection layer 22 and emitted from the holographic recording medium 21. These A-polarized beam component and of B-polarized beam component that have been reflected as a reflection beam is then turned into a parallel beam by the objective lens 34. Subsequently, the A-polarized beam component of this parallel beam is transmitted into the right side portion of the halving optical element 38 and then emitted therefrom as the S-polarized beam component, while the B-polarized beam component of this parallel beam is transmitted into the left side portion of the halving optical element 38 and then emitted therefrom as the S-polarized beam component. Since the S-polarized beam component thus emitted from the halving optical element 38 is reflected by the polarized beam splitter 37, it is impossible for the S-polarized beam component to reach the two-dimensional beam detector 36. Therefore, according to this recording/reconstructing apparatus, it is now possible to realize an excellent reconstructing signal-to-noise ratio.

The holographic recording medium according to the embodiment can be suitably employed for the multi-layer optical recording and reconstruction of information. This multi-layer optical recording and reconstruction of information may be of any type, i.e. either the transmission type or the reflection type.

Next, the present invention will be further explained with reference to specific examples as follows.

### EXAMPLE 1

4.54 g of 1,6-hexanediol diglycidyl ether (epoxy equivalent: 151; Nagase Chemitechs Co., Ltd.) employed as an epoxide monomer, 0.364 g of aluminum tris(ethylacetyl acetate) employed as a metal complex, and 0.01 g of 2-epoxyethyl naphthalene employed as a reagent for introducing an aromatic ring group into the matrix (hereinafter referred to as an aromatic ring group-introducing reagent for matrix) were mixed with each other in a dark room to obtain a mixture. The aromatic ring group-introducing reagent for matrix is a compound for introducing the same kind of aromatic ring-containing group as included in the radical polymeric monomer into the polymer matrix. This mixture was then allowed to dissolve with stirring at a temperature of 60° C. to prepare a solution of the metal complex.

Further, 4.55 g of 1,6-hexanediol diglycidyl ether (epoxy equivalent: 151; Nagase Chemitechs Co., Ltd.) employed as an epoxide monomer, and 0.545 g of triphenyl silanol employed as alkyl silanol were mixed with each other to obtain a mixture. This mixture was then allowed to dissolve with stirring at a temperature of 60° C. to prepare a silanol solution.

The solution of the metal complex and the silanol solution were mixed with each other with stirring. To the mixed solution thus stirred, 0.38 g of a radical polymeric monomer and 0.00625 g of a photo-radical polymerization initiator were added. 2-vinyl naphthalene was employed as the radical polymeric monomer and Irgacure 784 (Ciba Speciality Chemicals Co., Ltd.) was employed as the photo-radical polymerization initiator. Finally, the resultant mixture was subjected to defoaming to obtain a raw material solution for recording layer.

A pair of glass plates were superimposed with a spacer formed of a Teflon (registered trademark) sheet being interposed therebetween to create a space. Then, the aforementioned raw material solution for recording layer was poured into this space. The resultant structure was heated in an oven of 55° C. for 6 hours under a light-shielded condition, thereby manufacturing a test piece of the holographic recording medium bearing a recording layer having a thickness of 200 μm.

The test piece thus obtained was mounted on the rotary stage 13 of the hologram recording apparatus shown in FIG. 2 to perform the recording of hologram. As the light source device 1, a semiconductor laser (405 nm) was employed. The beam spot size on the test piece was 5 mm in diameter in each of the information beam 10 and the reference beam 11 and the intensity of the recording beam was adjusted to such that it became 7 mW/cm² as a total of the information beam 10 and the reference beam 11.

After finishing the recording of hologram, the information beam 10 was shut off by the electromagnetic shutter 8 and only the reference beam 11 was irradiated onto the test piece, admitting the diffracted beam from the test piece. Based on this fact, the existence of a transmission-type hologram recorded therein was confirmed. When the beam irradiation at an intensity of 70 mJ/cm² was performed, a maximum diffraction efficiency of 92% was indicated.

The recording performance of hologram was assessed by M/# (M number) representing a dynamic range of recording. This M/# can be defined by the following formula using ηᵢ. This ηᵢ represents a diffraction efficiency to be derived from i-th hologram as holograms of n pages are subjected to angular multiple recording/reconstruction until the recording at the same region in the recording layer of the holographic recording medium becomes no longer possible. This angular multiple recording/reconstruction can be performed by irradiating a predetermined beam to the holographic recording medium 12 while rotating the rotary stage 13.

$$M / \# = {\sum }_{i = l}^{n} \sqrt{η i}$$

It should be noted that the diffraction efficiency η was defined by the light intensity Iₜ to be detected at the beam detector 14 and the light intensity I_{d} to be detected at the beam detector 15 on the occasion when only the reference beam 11 was irradiated onto the holographic recording medium 12. Namely, the diffraction efficiency η was defined by an inner diffraction efficiency which can be represented by η=I_{d}/(Iₜ+I_{d}).

As the value of M/# of the holographic recording medium becomes larger, the dynamic range of recording can be further increased, thus enabling to enhance the multiple recording performances.

In this example, the M/# of the recording medium was 10.2, and the volumetric shrinkage due to the recording was 0.07%. Further, the residual ratio of the aromatic ring was determined according to the following method. First of all, soluble components were extracted from an unexposed recording medium by an organic solvent and the resultant insoluble matter was measured by solid NMR. In this measurement, the ratio between the proton intensity of aliphatic hydrocarbon and the proton intensity of aromatic hydrocarbon was calculated to determine the residual ratio of the aromatic ring. The residual ratio of the aromatic ring that could be defined by this method was 0.07%.

### EXAMPLES 2 AND 3

The holographic recording mediums of Example 2 and Example 3 were manufactured by repeating the same procedures as described in Example 1 except that the quantity of 2-epoxyethyl naphthalene employed as the aromatic ring group-introducing reagent for matrix was changed to 0.02 g and 0.03 g, respectively.

### EXAMPLE 4

The holographic recording medium of Example 4 was manufactured by repeating the same procedures as described in Example 1 except that the radical polymeric monomer was changed to 0.38 g of 1,4-diacryloyl benzene and the aromatic ring group-introducing reagent for matrix was changed to 0.02 g of 1,4-diacryloyl benzene.

### EXAMPLES 5 AND 6

The holographic recording mediums of Example 5 and Example 6 were manufactured by repeating the same procedures as described in Example 4 except that the quantity of 1,4-diacryloyl benzene employed as the aromatic ring group-introducing reagent for matrix was changed to 0.04 g and 0.06 g, respectively.

Thereafter, under the same conditions as described in Example 1, the M/# of the recording medium and the volumetric shrinkage were investigated, the results being summarized together with the residual ratio of the aromatic ring in the following Table 1.

### EXAMPLE 7

First of all, 8.16 g of 1,6-hexanediol diglycidyl ether (epoxy equivalent: 151; Nagase Chemitechs Co., Ltd.) employed as diglycidyl ether, 1.82 g of diethylene triamine employed amine, and 0.02 g of N-epoxyethyl carbazole (an aromatic ring group-introducing reagent for matrix) were mixed with each other to obtain a solution of polymer matrix precursor.

On the other hand, 0.38 g of N-vinyl carbazole employed as a radical polymeric monomer and 0.0625 g of Irgacure 784 (Ciba Speciality Chemicals Co., Ltd.) employed as a photo-radical polymerization initiator were mixed together to prepare a solution of monomer.

Then, the solution of polymer matrix precursor and the solution of monomer were mixed with each other and subjected to defoaming to obtain a solution of precursor for recording layer, which was then poured into a space created between a pair of glass plates which were superimposed with a spacer formed of a Teflon (registered trademark) sheet being interposed therebetween. The resultant structure was left to stand for 24 hours at room temperature (25° C.) under a light-shielded condition, thereby manufacturing a test piece of the holographic recording medium bearing a recording layer having a thickness of 200 μm.

### EXAMPLE 8

The holographic recording medium of Example 8 was manufactured by repeating the same procedures as described in Example 7 except that the radical polymeric monomer was changed to 0.38 g of tribromophenyl acrylate and the aromatic ring group-introducing reagent for matrix was changed to 0.02 g of epoxyethyl tribromobenzene.

### EXAMPLE 9

The holographic recording medium of Example 9 was manufactured by repeating the same procedures as described in Example 7 except that the radical polymeric monomer was changed to 0.38 g of 2,6-divinyl naphthalene and the aromatic ring group-introducing reagent for matrix was changed to 0.04 g of 2,6-epoxyethyl naphthalene.

Thereafter, under the same conditions as described above, the M/# of the recording medium and the volumetric shrinkage were investigated, the results being summarized together with the residual ratio of the aromatic ring in the following Table 1.

### COMPARATIVE EXAMPLE 1

5.0 g of 1,6-hexanediol diglycidyl ether (epoxy equivalent: 151; Nagase Chemitechs Co., Ltd.) employed as an epoxide monomer, and 0.4 g of aluminum tris(ethylacetyl acetate) employed as a metal complex were mixed with each other in a dark room to obtain a mixture. This mixture was then allowed to dissolve with stirring at a temperature of 60° C. to prepare a solution of the metal complex.

Further, 5.0 g of 1,6-hexanediol diglycidyl ether (epoxy equivalent: 151; Nagase Chemitechs Co., Ltd.) employed as an epoxide monomer, and 0.6 g of triphenyl silanol employed as alkyl silanol were mixed with each other to obtain a mixture. This mixture was then allowed to dissolve with stirring at a temperature of 60° C. to prepare a silanol solution.

The solution of the metal complex and the silanol solution were mixed with each other and the stirring thereof was continued. After the mixing, 5 g of the mixed solution was taken up and mixed with 0.38 g of a radical polymeric monomer and 0.00625 g of a photo-radical polymerization initiator. Vinyl naphthalene was employed as the radical polymeric monomer and Irgacure 784 (Ciba Speciality Chemicals Co., Ltd.) was employed as the photo-radical polymerization initiator. Finally, the resultant mixture was subjected to defoaming to obtain a raw material solution for recording layer.

A pair of glass plates were superimposed with a spacer formed of a Teflon (registered trademark) sheet being interposed therebetween to create a space. Then, the aforementioned raw material solution for recording layer was poured into this space. The resultant structure was heated in an oven of 55° C. for 6 hours under a light-shielded condition, thereby manufacturing a test piece of the holographic recording medium bearing a recording layer having a thickness of 200 μm.

The test piece thus obtained was mounted on the rotary stage 13 of the hologram recording apparatus shown in FIG. 2 to perform the recording of hologram. As the light source device 1, a semiconductor laser (405 nm) was employed. The beam spot size on the test piece was 5 mm in diameter in each of the information beam 10 and the reference beam 11 and the intensity of the recording beam was adjusted to such that it became 7 mW/cm² as a total of the information beam 10 and the reference beam 11.

After finishing the recording of hologram, the information beam 10 was shut off by the electromagnetic shutter 8 and only the reference beam 11 was irradiated onto the test piece, admitting the diffracted beam from the test piece. Based on this fact, the existence of a transmission-type hologram recorded therein was confirmed. When the beam irradiation at an intensity of 70 mJ/cm² was performed, a maximum diffraction efficiency of 80% was indicated.

In this example, the M/# of the recording medium was 8.0, and the volumetric shrinkage due to the recording was 0.10%.

TABLE 1

| | | | Aromatic |
|---|---|---|---|
| | | Volumetric | ring |
| | | shrinkage | residual ratio |
| | M/# | (%) | (%) |
| Ex. 1 | 10.2 | 0.07 | 0.07 |
| Ex. 2 | 10.5 | 0.05 | 0.15 |
| Ex. 3 | 10.3 | 0.04 | 0.21 |
| Ex. 4 | 9.5 | 0.06 | 0.09 |
| Ex. 5 | 9.8 | 0.05 | 0.19 |
| Ex. 6 | 9.7 | 0.04 | 0.28 |
| Ex. 7 | 10.1 | 0.05 | 0.16 |
| Ex. 8 | 10.2 | 0.04 | 019 |
| Ex. 9 | 10.1 | 0.03 | 0.24 |
| Comp. Ex. 1 | 8 | 0.10 | 0 |

As seen from Table 1, when the same kind of aromatic ring-containing group as included in the radical polymeric monomer exists in the polymer matrix, the diffraction efficiency by the exposure as well as the dynamic range of recording is enabled to increase, thus making it possible to suppress the volumetric shrinkage.

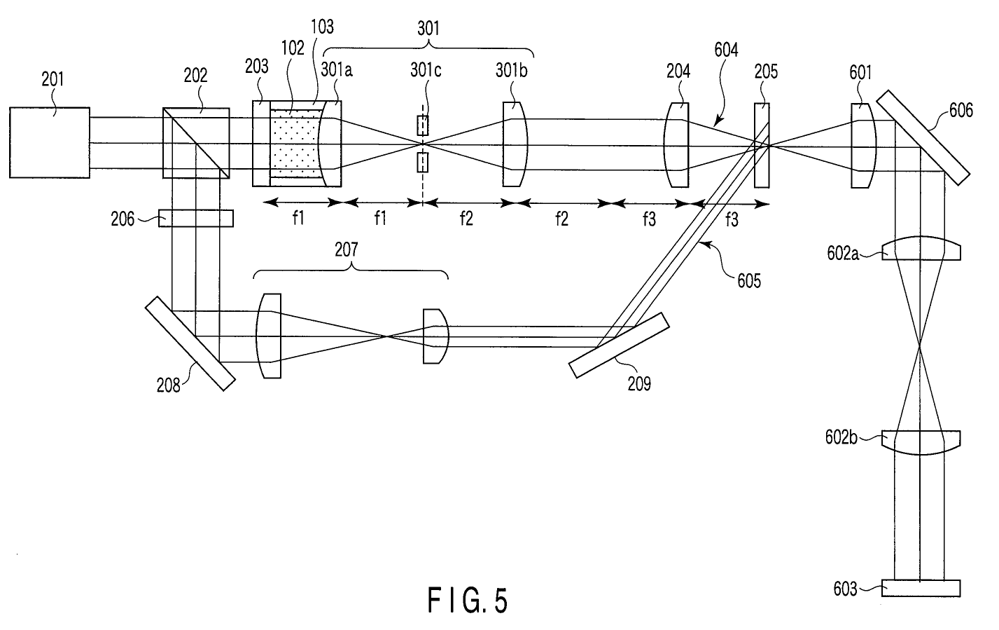

The holographic recording medium according to one embodiment as described above can be applied to the optical information recording/reconstructing apparatus as shown in FIG. 5 for example. FIG. 5 illustrates one example of structural diagram of the optical system of the optical information recording/reconstructing apparatus. Herein, the optical system means an optical system interposed between a spatial light modulator and a holographic recording medium.

In the optical information recording/reconstructing apparatus shown in FIG. 5, an information beam and a reference beam are irradiated onto the information recording layer of a holographic recording medium 205. This pair of beams thus irradiated interferes inside the information recording layer, thereby enabling information to be recorded as a holography. The information thus recorded in the information recording layer of the holographic recording medium 205 can be reconstructed by the irradiation of the reference beam. In the case of the optical information recording/reconstructing apparatus shown in FIG. 5, there is employed a two-beam system wherein the information beam is irradiated onto the recording layer of the recording medium at a different angle from that of the reference beam to be irradiated onto the recording layer of the recording medium, thereby causing the information beam to interfere with the reference beam.

As shown in FIG. 5, the optical information recording/reconstructing apparatus comprises a semiconductor laser 201 for emitting a laser beam, a polarization beam splitter 202, a spatial light modulator 203, a retaining member 103 filled with a transmissive substance 102, a spatial filter 301, objective lens 204 and 601, a wavelength plate 206, mirrors 208, 209 and 606, a beam-reducing optical system 207, a relay lens 602a and 602b, and a two-dimensional imaging device 603. As the two-dimensional imaging device 603, it is possible to employ a CMOS or a CCD for example.

The laser beam of linearly polarized light that has been emitted from the semiconductor laser 201 is divided into a pair of beams by the polarization beam splitter 202. One of these beams thus divided passes through the polarization beam splitter 202 and the other beam is reflected by the polarization beam splitter 202. The beam that has passed through the polarization beam splitter 202 enters into the spatial light modulator 203, in which the beam is subjected to light intensity modulation or phase modulation, thereby enabling the beam to convert into an information beam carrying information.

As the spatial light modulator 203, it is possible to employ a transmission-type liquid crystal device. The information beam is a beam carrying information (data page) of binarized pattern and incorporated with an error-correcting code derived from the digital-encoding of the information to be recorded. The information beam of this kind is accompanied with a large number of clear and dark points.

The information beam passes through the transmissive substance and enters into the spatial filter 301. The spatial filter 301 is constituted by a pair of relay lens 301a and 301b, and an iris diaphragm 301c. The relay lens 301a and 301b are designed to transmit the information beam that has been passed through the spatial light modulator 203 to the objective lens 204. The iris diaphragm 301c is designed to remove redundant higher-order diffracted beam or noise from the information beam transmitted from the relay lens 301a.

The information beam 604 which is now free from redundant higher-order diffracted beam or noise is permitted to pass through and converged by the objective lens (condensing lens) 204 and then transmitted to irradiate the holographic recording medium 205.

On the other hand, the beam that has been divided by the polarization beam splitter 202 and reflected by the polarization beam splitter 202 is polarized in the same direction as the information beam by the effect of wavelength plate 206 and then reduced in size into a predetermined beam diameter by the effect of beam-reducing optical system 207. After being reduced in beam diameter, the beam is irradiated, as a reference beam 605, to the holographic recording medium 205.

In the information recording layer of the holographic recording medium 205, the information beam 604 that has been irradiated in this manner is caused to interfere with the reference beam 605, thereby enabling the information to be recorded three-dimensionally as fine interference fringes.

By enabling the holographic recording medium 205 to move a predetermined shifting distance by a driving apparatus (not shown), information can be successively recorded as described above, thus performing multiple recording.

When reconstructing the information thus recorded in the information recording layer of holographic recording medium 205, the reference beam 605 is irradiated onto the information recording layer of holographic recording medium 205 where the information is recorded. The reference beam that has been transmitted from the interference fringes recorded in the information recording layer is then permitted to pass through the surface which is disposed opposite to the reference beam-irradiating surface of holographic recording medium 205, thereby obtaining a transmitted diffracted beam. This transmitted diffracted beam is then introduced into the objective lens 601 and turned into parallel rays, which are then reflected by the mirror 606.

Subsequently, this reflected beam is processed by relay lens 602a and 602b to create an image on the two-dimensional imaging device 603, thus obtaining a two-dimensional image from this signal beam. On the occasion of image reconstruction, the holographic recording medium 205 is caused to move a predetermined shifting distance by a driving apparatus (not shown), thereby enabling the recorded information to be successively reconstructed as described above.

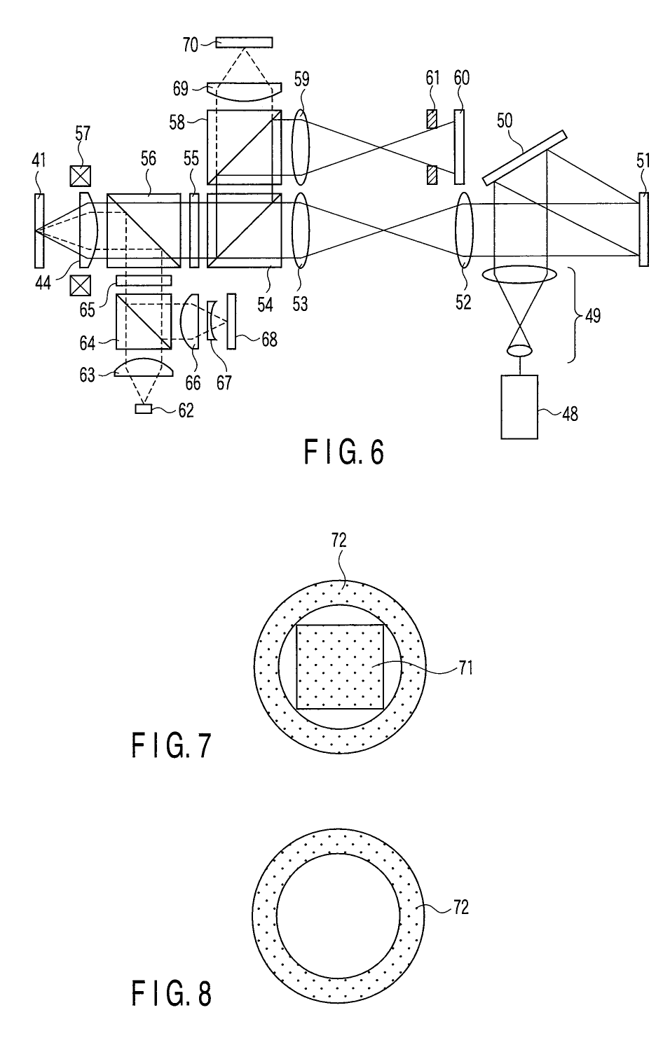

The reflection-type holographic recording medium according to this embodiment can be applied to the optical information recording/reconstructing apparatus as shown in FIG. 6. In the optical information recording/reconstructing apparatus shown in FIG. 6, a coaxial interference method is employed wherein the information beam and the modulated reference beam are created by a single spatial light modulator, thereby executing the recording of hologram.

As the light source device 48, it is preferable, in view of coherence, to employ a laser which is linearly polarized. More specifically, it is possible to employ a semiconductor laser, an He—Ne laser, an argon laser and a YAG laser. This light source device 48 is provided with function to adjust the emission wavelength thereof.

The beam emitted from the light source device 48 is expanded by a beam expander 49 and adjusted in form into parallel beam. The beam thus adjusted in form is irradiated, via a mirror 50, to a reflection-type spatial light modulator 51. This reflection-type spatial light modulator 51 is provided with a plurality of pixels which are arrayed two-dimensionally and in a lattice pattern, each of these pixels being capable of changing the direction of reflecting beam. Further, this reflection-type spatial light modulator 51 is enabled, through the changing in direction of polarization of the reflecting beam by each of these pixels, to concurrently generate the information beam carrying information as a two-dimensional pattern and the reference beam that has been spatially modulated.

As specific examples of this reflection-type spatial light modulator 51, it is possible to employ, for example, a digital mirror device, a reflection-type liquid crystal device, a reflection-type modulator device utilizing magneto-optical effects, etc. In the apparatus shown in FIG. 6, the digital mirror device is employed as a reflection-type spatial light modulator. In this reflection-type spatial light modulator 51, a modulation pattern as shown in FIG. 7 is enabled to display, so that a central portion of optical axis can be used as an information beam region 71 and a peripheral portion thereof can be used as a reference beam region 72.

The recording beam that has been reflected by the reflection-type spatial light modulator 51 is permitted to enter, via imaging lens 52 and 53, into a polarized beam splitter 54. In this case, the recording beam is adjusted in the direction of polarization at the moment of emission from the light source device 48 so as to enable the recording beam to pass through the polarized beam splitter 54. The recording beam that has passed through the polarized beam splitter 54 is enabled to pass through an optical element 55 for optical rotation and to enter into a dichroic prism 56. This dichroic prism 56 is designed so as to enable the wavelength of recording beam to pass therethrough.

The beam that has passed through the dichroic prism 56 is then irradiated, by an objective lens 44, to an optical recording medium 41 and converged so as to make the beam diameter thereof minimum at the reflecting layer of optical recording medium 41. As the optical element 55 for optical rotation, it is possible to employ a half- or quarter-wavelength plate, etc. As a recording beam where a central portion of optical axis is occupied by the information beam and a peripheral portion thereof is occupied by the reference beam as described above is irradiated onto the optical recording medium 41, the information beam interferes with the reference beam in the interior of recording layer, thus forming a hologram in the optical recording medium 41.

A modulation pattern to be displayed in the reflection-type spatial light modulator 51 on the occasion of reconstructing the information that has been recorded is shown in FIG. 8. It will be recognized from the comparison between the modulation pattern of the recording beam shown in FIG. 7 and the modulation pattern shown in FIG. 8 that the region of reference beam existing at the peripheral portion thereof is the same as that of FIG. 7. This reference beam is irradiated onto the optical recording medium 41 in the same manner as performed when recording. Part of the reference beam is diffracted by the hologram as it passes through the optical recording medium 41, enabling it to become a reconstructing beam.

The reconstructing beam is reflected by a reflecting layer and then permitted to pass through an objective lens 57 and the dichroic prism 56. Thereafter, when passing through the optical element 55 for optical rotation, the reconstructing beam is enabled to contain a polarized beam component which is different from the reference beam, after which the reconstructing beam is reflected by the polarized beam splitter 54. The rotation angle of the optical element 55 for optical rotation is adjusted such that the reflectance of reconstructing beam at the polarized beam splitter 54 may becomes the highest.

Most of the reconstructing beam that has been reflected by the polarized beam splitter 54 is reflected by a beam splitter 58 and then reproduced, via an image-forming lens 59, into a reconstructed image on the two-dimensional photo-detector 60. On the other hand, the reference beam which could not be diffracted by the hologram is turned into a transmissive beam and reproduced as an image on the two-dimensional photo-detector 60 in the same manner as in the case of the reconstructing beam. On this occasion, since the central portion is occupied by the reconstructing beam and the peripheral portion is occupied by the reference beam, they can be easily separated spatially. It should be noted that, for the purpose of enhancing the signal-to-noise ratio of reconstructing signals, an iris 61 may be disposed in front of the photo-detector 60, thereby shut off the portion of reference beam.

According to the embodiment of the present invention, it is possible to provide a holographic recording medium which is high in recording capacity and in refractive index modulation and is minimal in volumetric change that may be caused by the beam irradiation.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A holographic recording medium comprising a recording layer, the recording layer comprising a radical polymeric monomer having an aromatic ring-containing group and a polymeric group; a polymer matrix having the aromatic ring-containing group; and a photo-radical polymerization initiator.

2. The holographic recording medium according to claim 1, wherein the aromatic ring-containing group is selected from the group consisting of phenyl group, phenylene group, naphthyl group, naphthylene group and carbazole group.

3. The holographic recording medium according to claim 1, wherein the polymeric group is selected from the group consisting of vinyl group, acrylic group and methacrylic group.

4. The holographic recording medium according to claim 1, wherein the radical polymeric monomer is selected from the group consisting of vinylnaphthalene, vinylcarbazole, tribromophenyl acrylate, styrene and divinylphenylene.

5. The holographic recording medium according to claim 1, wherein the radical polymeric monomer is contained in the recording layer at a content ranging from 1 to 40 parts by weight based on 100 parts by weight of the recording layer.

6. The holographic recording medium according to claim 1, wherein the radical polymeric monomer is contained in the recording layer at a content ranging from 5 to 15 parts by weight based on 100 parts by weight of the recording layer.

7. The holographic recording medium according to claim 1, wherein the polymer matrix is formed of a three-dimensional cross-linking polymer.

8. The holographic recording medium according to claim 7, wherein the three-dimensional cross-linking polymer is obtained from polymerization of epoxide monomer.

9. The holographic recording medium according to claim 7, wherein the three-dimensional cross-linking polymer is obtained from a polymerization method of epoxide monomer, a polymerization method including epoxy-amine polymerization, epoxy-acid anhydride polymerization and epoxy homopolymerization.

10. The holographic recording medium according to claim 1, wherein the polymer matrix contains the aromatic ring-containing group at a content ranging from 0.01% to 5%.

11. The holographic recording medium according to claim 1, wherein the polymer matrix contains the aromatic ring-containing group at a content ranging from 0.01% to 0.5%.

12. The holographic recording medium according to claim 1, wherein the photo-radical polymerization initiator is selected from the group consisting of imidazole derivatives, organic azide compounds, titanocene, organic peroxides and thioxanthone derivatives.

13. The holographic recording medium according to claim 1, wherein the photo-radical polymerization initiator is incorporated at a content ranging from 0.1 to 10% by weight based on the radical polymeric monomer.

14. The holographic recording medium according to claim 1, wherein the photo-radical polymerization initiator is incorporated at a content ranging from 0.5 to 6% by weight based on the radical polymeric monomer.

15. The holographic recording medium according to claim 1, wherein the recording layer further comprises at least one selected from the group consisting of a sensitizing agent, a silane coupling agent and a plasticizer.

16. The holographic recording medium according to claim 1, wherein the recording layer has a thickness ranging from 0.1 to 5 mm.

17. The holographic recording medium according to claim 1, wherein the recording layer has a thickness ranging from 0.2 to 2 mm.

18. An optical information recording/reconstructing apparatus comprising:
the aforementioned holographic recording medium according to claim 1;
a recording portion for recording information in the medium; and
a reconstructing portion for reconstructing the information recorded in the medium.
